(19) United States
(12) Patent Application Publication
(10) Pub. No.: US 2007/0048545 A1
(43) Pub. Date: Mar. 1, 2007

(54) Electron-transporting layer for white OLED device

(75) Inventors: Tukaram K. Hatwar, Penfield, NY (US); William J. Begley, Webster, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/216,383

(22) Filed: Aug. 31, 2005

(51) Int. Cl. H01L 51/54; H05B 33/12

(52) U.S. Cl. 428/690; 428/917; 313/504; 313/506; 257/E51.049; 257/E51.05; 257/E51.043

(57) ABSTRACT

An OLED device including a cathode, an anode, one or more light-emitting layers disposed between the anode and cathode to produce white light and a layer disposed between the light-emitting layer(s) and the cathode. The layer includes a polycyclic aromatic hydrocarbon compound that has the lowest LUMO value of the compounds in the layer, in an amount greater than or equal to 10% by volume and less than 100% by volume of the layer; at least one second compound exhibiting a higher LUMO value than the polycyclic aromatic hydrocarbon compound, where at least one of the second compounds is a low voltage electron-transporting material, and the total amount of such second compounds(s) is less than or equal to 90% by volume of the layer; and a metallic material based on a metal having a work function less than 4.2 eV.

### CROSS REFERENCE TO RELATED APPLICATIONS

Reference is made to commonly assigned U.S. patent application Ser. No. 11/077,218, filed Mar. 10, 2005 by Begley et al., entitled “Organic Light-Emitting Devices With Mixed Electron Transport Materials”;

U.S. patent application Ser. No. 11/110,071, filed Apr. 20, 2005 by Hatwar et al., entitled “Tandem OLED Device”; and

U.S. patent application Ser. No. ______, filed concurrently herewith, by Hatwar et al., entitled “Intermediate Connector for a Tandem OLED Device”.

### FIELD OF THE INVENTION

The present invention relates to OLED devices, and more particularly, to an electron-transporting layer for use in such devices.

### BACKGROUND OF THE INVENTION

Organic electroluminescent (EL) devices or organic light-emitting diodes (OLEDs) are electronic devices that emit light in response to an applied potential. The structure of an OLED includes, in sequence, an anode, an organic EL unit, and a cathode. The organic EL unit disposed between the anode and the cathode is commonly comprised of an organic hole-transporting layer (HTL) and an organic electron-transporting layer (ETL). Holes and electrons recombine and emit light in the ETL near the interface of HTL/ETL. Tang et al., “Organic Electroluminescent Diodes”, Applied Physics Letters, 51, 913 (1987), and commonly assigned U.S. Pat. No. 4,769,292 demonstrated highly efficient OLEDs using such a layer structure. Since then, numerous OLEDs with alternative layer structures have been disclosed. For example, there are three layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of Doped Organic Thin Films”, Journal of Applied Physics, 65, 3610 (1989). The LEL commonly includes a host material doped with a guest material wherein the layer structures are denoted as HTL/LEL/ETL. Further, there are other multilayer OLEDs that contain more functional layers in the devices. At the same time, many kinds of EL materials are also synthesized and used in OLEDs. These new structures and new materials have further resulted in improved device performance.

An OLED is actually a current-driven device. Its luminance is proportional to current density, but its lifetime is inversely proportional to current density. In order to achieve high brightness, an OLED has to be operated at a relatively high current density, but this will result in a short lifetime. Thus, it is critical to improve the luminous efficiency of an OLED while operating at the lowest possible current density consistent with the intended luminance requirement to increase the operational lifetime.

In addition to continued need to provide OLEDs having improved lifetime and efficiency, it is desirable to improve manufacturability of OLED devices. One way to simplify manufacturing is to limit shadow mask patterning and instead provide a white or broadband light-emitting OLED with color filters. For lowest power consumption, it is often advantageous for the chromaticity of the white light-emitting OLED to be close to CIE D₆₅, i.e., CIE x=0.31 and CIE y=0.33. This is particularly the case for so-called RGBW displays having red, green, blue, and white pixels. However, many white or broadband OLED devices have multiple emissive layers, which results in higher drive voltage. Thus, there is a need to reduce the drive voltage and still achieve a desirable white point. As a part of this need, there are continuing needs for organic EL device components, such as electron-transporting materials and or electron-injecting materials, that will provide even lower device drive voltages and hence lower power consumption, while maintaining high luminance efficiencies and long lifetimes combined with high color purity.

A useful class of electron-transporting materials is that derived from metal chelated oxinoid compounds including chelates of oxine itself, also commonly referred to as 8-quinolinol or 8-hydroxyquinoline. Tris(8-quinolinolato)aluminum (III), also known as Alq or Alq₃, and other metal and non-metal oxine chelates are well known in the art as electron-transporting materials. Tang et al., in U.S. Pat. No. 4,769,292 and VanSlyke et al., in U.S. Pat. No. 4,539,507 lower the drive voltage of the EL devices by teaching the use of Alq as an electron-transporting material in the luminescent layer or luminescent zone.

Baldo et al., in U.S. Pat. No. 6,097,147 and Hung et al., in U.S. Pat. No. 6,172,459 teach the use of an organic electron-transporting layer adjacent to the cathode so that when electrons are injected from the cathode into the electron-transporting layer, the electrons traverse both the electron-transporting layer and the light-emitting layer.

Tamano et al., in U.S. Pat. No. 6,150,042 teaches use of hole-injecting materials in an organic EL device. Examples of electron-transporting materials useful in the device are given and included therein are mixtures of electron-transporting materials. There is no reference to low drive voltage with the devices.

Seo et al., in US 2002/0086180A1 teaches the use of a 1:1 mixture of Bphen, (also known as 4,7-diphenyl-1, 10-phenanthroline or bathophenanthroline) as an electron transporting material, and Alq as an electron injection material, to form an electron transporting mixed layer. However, the Bphen/Alq mix of Seo et al., shows inferior stability.

Kido et al., in U.S. Pat. No. 6,013,384 teaches an EL device with at least one luminescent layer having an organic compound doped with a metal capable of acting as a dopant. However, these devices do not have the desired EL characteristics in terms of stability of the components in combination with low drive voltages.

The problem to be solved therefore, is to provide an OLED device having a light-emitting layer (LEL) that exhibits good luminance efficiency and stability while at the same time requiring low drive voltages for reduced power consumption.

### SUMMARY OF THE INVENTION

It is an object of the present invention to make an OLED device having a low drive voltage, high efficiency, and long lifetime.

It is another object of the present invention to make a broadband or white light-emitting OLED device having a low drive voltage, high efficiency, long lifetime, and appropriate chromaticity.

These objects are achieved by an OLED device comprising:

a) a cathode, an anode, one or more light-emitting layers disposed between the anode and cathode to produce white light; and

b) a layer disposed between the light-emitting layer(s) and the cathode including:
i) a polycyclic aromatic hydrocarbon compound that has the lowest LUMO value of the compounds in the layer, in an amount greater than or equal to 10% by volume and less than 100% by volume of the layer;
ii) at least one second compound exhibiting a higher LUMO value than the polycyclic aromatic hydrocarbon compound, where at least one of the second compounds is a low voltage electron-transporting material, and the total amount of such second compounds(s) is less than or equal to 90% by volume of the layer; and
iii) a metallic material based on a metal having a work function less than 4.2 eV.

### ADVANTAGES

It is an advantage of this invention that it provides an OLED device that has better stability and operates at a lower voltage. It is a further advantage of this invention that can provide a lower operating voltage for the OLED device without a color shift that is sometimes seen with materials that provide a lower operating voltage.

### BRIEF DESCRIPTION OF THE DRAWINGS

FIG. 1 shows a cross-sectional view of one embodiment of the present invention wherein a polycyclic aromatic hydrocarbon compound, a second compound, and a metallic material are located in one layer.

### DETAILED DESCRIPTION OF THE INVENTION

The invention is generally described above. A white-light-emitting OLED device of the invention is a multilayer electroluminescent device comprising a cathode, an anode, one or more light-emitting layer(s) (LEL), and a further layer, which will be described in detail. The white-light-emitting OLED device can further include hole-injecting layer(s) (if necessary), electron-injecting layer(s) (if necessary), hole-transporting layer(s), and electron-transporting layer(s). The further layer of the invention is located on the cathode side of the light-emitting layers and includes at least two different compounds, a polycyclic aromatic hydrocarbon compound and at least one second compound, and also includes a metallic material. In some embodiments, the further layer and the electron-injecting layer of the device, can be provided by the same layer. The polycyclic aromatic hydrocarbon compound has a Lowest Unoccupied Molecular Orbital (LUMO) value that is the lowest of the compounds in the layer. The second compound(s) has a higher LUMO value(s) than the polycyclic aromatic hydrocarbon compound and at least one of the second compound(s) is a low voltage electron-transporting material.

Further embodiments of the invention support more than one second compound in said layer. For simplicity, preferred embodiments of the invention are those that include one polycyclic aromatic hydrocarbon compound and one second compound. The amount of the polycyclic aromatic hydrocarbon compound present in the layer is greater than or equal to 10% by volume, but less than 100%. The total amount of the second compound(s), the low voltage electron-transporting material(s), present in the layer is less than or equal to 90% by volume, but greater than 0%. Metallic materials useful for doping are not restricted to specific ones as long as it is a metal that can reduce one or more of the organic compounds in the layer. The amount of metallic material is more than 0.1% and less than 15% by volume.

As used herein, the term “low voltage electron-transporting material” means those materials that, when incorporated alone into the electron transporting layer, result in drive voltages of 13 volts or less. Low voltage electron transport materials with drive voltages of 10 volts or less are also useful as second compounds of the invention while materials of 8 volts or less are preferred as second compounds. Such materials have been described in detail by Begley et al. in U.S. patent application Ser. No. 11/077,218, filed Mar. 10, 2005, entitled “Organic Light-Emitting Devices With Mixed Electron Transport Materials.

White light-emitting OLED devices made in accordance with the present invention require lower drive voltages to operate than devices employing the second compound, the low voltage electron-transport material, alone in the layer. Embodiments of the invention can also exhibit high operational stability, give low voltage rises over the lifetimes of the devices, and can be produced consistently and with high reproducibility to provide good light efficiency.

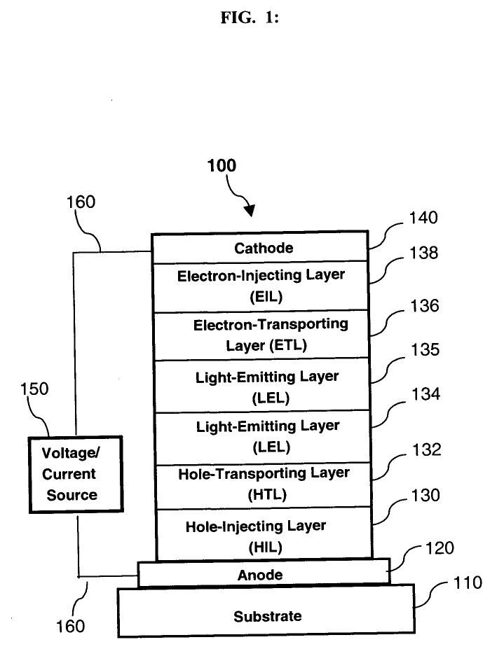

FIG. 1 shows one embodiment of the invention in which hole-injecting, hole-transporting, electron-transporting, and electron-injecting layers are present. The electron-transporting layer in this embodiment is the said further layer including the polycyclic aromatic hydrocarbon compound, the second compound(s), and the metallic material, and is adjacent to the electron-injecting layer. When there is no electron-injecting layer present, the said further layer is adjacent to the cathode. In other embodiments there can be more than one hole-injecting, electron-injecting and electron-transporting layers. When more than one electron-transporting layer is present, the said further layer of the invention can be adjacent to the cathode while the additional electron-transporting layers are adjacent to the light-emitting layer(s), or the said further layer of the invention can be adjacent to the light-emitting layer(s) with the additional electron-transporting layers adjacent to the cathode.

The further layer as described above, can be an emitting or non-emitting layer. It functions to transport electrons with the result that the OLED device requires a lower voltage for operation than with either the polycyclic aromatic hydrocarbon or second compound alone. When emitting, the electroluminescence from said layer can enhance the emission from the other emitting layer. When non-emitting, either the polycyclic aromatic hydrocarbon or second compound or both should be essentially colorless and non-emitting.

One useful embodiment of the invention is a white-light-emitting OLED device comprising an anode, an optional hole-transporting layer disposed over the anode, a yellow, orange, or red light-emitting layer disposed over the cathode (and over the hole-transporting layer, if present) and doped with a yellow-light-emitting compound, a blue-light-emitting layer with a blue-light-emitting compound disposed directly on the yellow, orange, or red light-emitting layer, an electron-transporting layer disposed over the blue-light-emitting layer and including:

i) a polycyclic aromatic hydrocarbon compound that includes at least 2 fused rings and has the lowest LUMO value of the compounds in the layer, in an amount greater than or equal to 10% and less than 100% by volume of the layer;

ii) at least one second compound exhibiting a higher LUMO value than the polycyclic aromatic hydrocarbon compound, where at least one of the second compounds is a low-voltage electron-transporting material, the total amount of such second compounds(s) being less than or equal to 90% by volume of the layer; and

iii) a metallic material based on a metal having a work function less than 4.2 eV; and

iv) a cathode disposed over the electron-transporting layer.

Another useful embodiment of the invention is a white-light-emitting OLED device comprising an anode, an optional hole-transporting layer disposed over the anode, a yellow, orange, or red-light-emitting layer disposed over the anode (and over the hole-transporting layer, if present) and doped with a yellow-light-emitting compound, a blue-light-emitting layer with a blue-light-emitting compound disposed directly on the yellow, orange, or red light-emitting layer, an electron-transporting layer disposed over the blue-light-emitting layer and including:

i) a polycyclic aromatic hydrocarbon compound that includes at least 3 fused rings and has the lowest LUMO value of the compounds in the layer, in an amount greater than or equal to 10% and less than 100% by volume of the layer;

ii) at least one second compound exhibiting a higher LUMO value than the polycyclic aromatic hydrocarbon compound, where at least one of the second compounds is a low-voltage electron-transporting material, the total amount of such second compounds(s) being less than or equal to 90% by volume of the layer; and

iii) a metallic material based on a metal having a work function less than 4.2 eV; and

iv) a cathode disposed over the electron-transporting layer.

The polycyclic aromatic hydrocarbon compound comprises carbocyclic rings. As used herein and throughout this application, the term carbocyclic rings or groups are generally as defined by the Grant & Hackh's Chemical Dictionary, Fifth Edition, McGraw-Hill Book Company. A carbocyclic ring is any aromatic or non-aromatic ring system wherein the ring comprises only carbon atoms. The polycyclic aromatic hydrocarbon compounds of this invention comprise at least two fused rings, at least one of which is aromatic. Carbocyclic ring systems useful for the current invention for the polycyclic aromatic hydrocarbon are selected from anthracenes, phenanthrenes, tetracenes, xanthenes, perylenes, fluoranthenes, and periflanthrenes, any of which can be further substituted.

In one embodiment, the polycyclic aromatic hydrocarbon compound can be selected from naphthacene derivatives that are represented by Formula A: 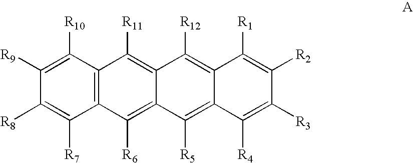
wherein:

R₁, R₂, R₃, R₄, R₅, R₆, R₇, R₈, R₉, R₁₀, R₁₁, and R₁₂ are independently selected as hydrogen or substituents;

provided that any of the indicated substituents can join to form further fused rings.

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group can be halogen or can be bonded to the remainder of the molecule by an atom of carbon, silicon, oxygen, nitrogen, phosphorous, sulfur, selenium, or boron. The substituent can be, for example, halogen, such as chloro, bromo or fluoro; nitro; hydroxyl; cyano; carboxyl; or groups which can be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1(N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which can be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents can themselves be further substituted one or more times with the described substituent groups. The particular substituents used can be selected by those skilled in the art to attain desirable properties for a specific application and can include, for example, electron-withdrawing groups, electron-donating groups, and steric groups. When a molecule can have two or more substituents, the substituents can be joined together to form a ring such as a fused ring unless otherwise provided. Generally, the above groups and substituents thereof can include those having up to 48 carbon atoms, typically 1 to 36 carbon atoms and usually less than 24 carbon atoms, but greater numbers are possible depending on the particular substituents selected.

Preferentially, the polycyclic aromatic hydrocarbon compound of the invention represented by Formula A are those in which at least one of R₁, R₂, R₃, R₄, R₅, R₆, R₇, R₈, R₉, R₁₀, R₁₁, and R₁₂ are independently selected from alkyl and aryl groups.

In another embodiment, the polycyclic aromatic hydrocarbon compound can be selected from anthracene derivatives that are represented by Formula B: 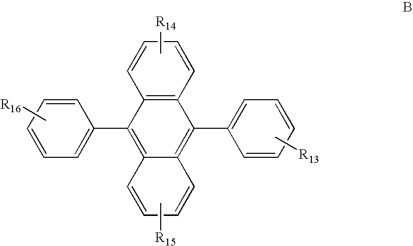
wherein:

R₁₃, R₁₄, R₁₅ and R₁₆ represent hydrogen or one or more substituents selected from the following groups:

Group 1: hydrogen, alkyl and alkoxy groups typically having from 1 to 24 carbon atoms;

Group 2: a ring group, typically having from 6 to 20 carbon atoms;

Group 3: the atoms necessary to complete a carbocyclic fused ring group such as naphthyl, anthracenyl, pyrenyl, and perylenyl groups, typically having from 6 to 30 carbon atoms;

Group 4: the atoms necessary to complete a heterocyclic fused ring group such as furyl, thienyl, pyridyl, and quinolinyl groups, typically having from 5 to 24 carbon atoms;

Group 5: an alkoxylamino, alkylamino, and arylamino group typically having from 1 to 24 carbon atoms; and

Group 6: fluorine, chlorine, bromine and cyano radicals.

More specifically, the polycyclic aromatic hydrocarbon compound of the invention can be selected from compounds represented by the following structures:

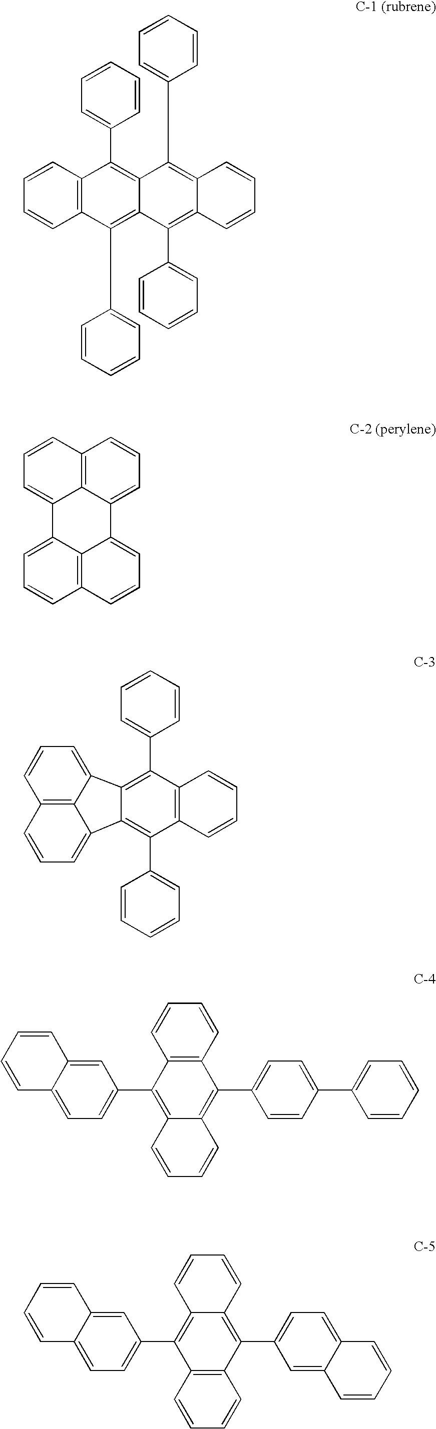

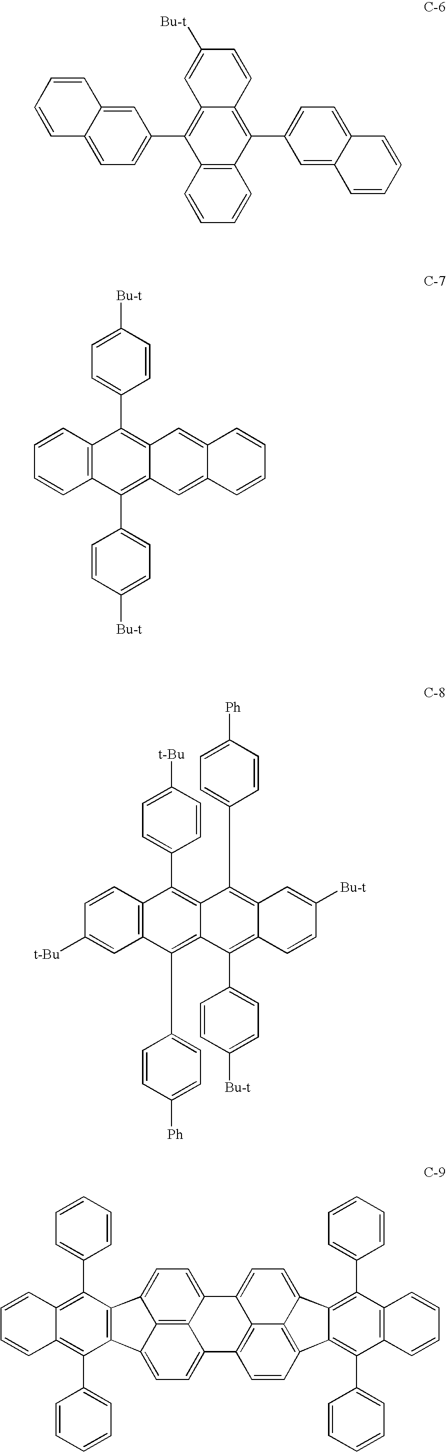

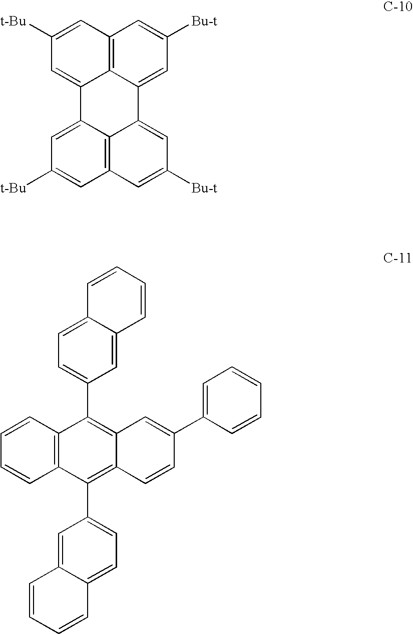

Also included in the above structures are compounds containing the depicted structural features with substituents suitable to render said structures with the desired properties to function as polycyclic aromatic hydrocarbon compound materials of the invention.

It is a requirement of the polycyclic aromatic hydrocarbon compound that it have the lowest LUMO value of the compounds in the further layer. A particularly preferred polycyclic aromatic hydrocarbon compound is rubrene (Structure C-1) or a derivative thereof.

The second compound can optionally comprise carbocyclic and/or heterocyclic rings. A heterocyclic ring is any aromatic or non-aromatic ring system containing both carbon and non-carbon atoms such as nitrogen (N), oxygen (O), sulfur (S), phosphorous (P), silicon (Si), gallium (Ga), boron (B), beryllium (Be), indium (In), aluminum (Al), and other elements found in the periodic table useful in forming ring systems. For the purpose of this invention, also included in the definition of a heterocyclic ring are those rings that include coordinate bonds. The definition of a coordinate bond can be found in Grant & Hackh's Chemical Dictionary, page 91. In essence, a coordinate bond is formed when electron rich atoms such as O or N, donate a pair of electrons to electron deficient atoms such as Al or B. One such example is found in tris(8-quinolinolato)aluminum(III), also referred to as Alq, wherein the nitrogen on the quinoline moiety donates its lone pair of electrons to the aluminum atom thus forming the heterocycle and hence providing Alq with a total of 3 fused rings. The definition of work function can be found in CRC Handbook of Chemistry and Physics, 70th Edition, 1989-1990, CRC Press Inc., page F-132 and a list of the work functions for various metals can be found on pages E-93 and E-94. Carbocyclic and heterocyclic ring systems useful for the current invention for the second compounds are selected from metal and non-metal chelated oxinoids, anthracenes, bipyridyls, butadienes, imidazoles, phenanthrenes, phenanthrolines, styrylarylenes, benzazoles, buckministerfullerene-C₆₀ (also known as buckyball or fullerene-C₆₀), tetracenes, xanthenes, perylenes, coumarins, rhodamines, quinacridones, dicyanomethylenepyrans, thiopyrans, polymethines, pyrylliums, fluoranthenes, periflanthrenes, silacyclopentadienes or siloles, thiapyrylliums, triazines, carbostyryls, metal and non-metal chelated bis(azinyl)amines, metal and non-metal chelated bis(azinyl)methenes.

The second compound of the invention can be selected from metal oxinoid compounds represented by Formula D: 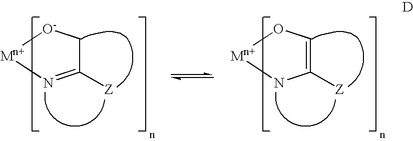
wherein

M represents a metal;

n is an integer of from 1 to 4; and

Z independently in each occurrence represents the atoms completing a nucleus having at least two fused aromatic rings.

The second compound can also be selected from compounds represented by Formula E:
(R^{S}-Q)₂-M-O-L E
wherein

M is a metal or non-metal;

Q in each occurrence represents a substituted 8-quinolinolato ligand;

R^{S} represents an 8-quinolinolato ring substituent chosen to block sterically the attachment of more than two substituted 8-quinolinolato ligands to the aluminum atom; and

L is a phenyl or aromatic fused ring moiety, which can be substituted with hydrocarbon groups such that L has from 6 to 24 carbon atoms.

The second compound(s) can be selected from compounds represented by Formulas D or E, with the provisos that at least one second compound is a low voltage electron-transporting material and that the second compound has the highest LUMO value. Additional second compounds can be selected having Formulas D and E. Additional examples of second compounds represented by Formula E can be found in Bryan et al., U.S. Pat. No. 5,141,671, incorporated herein by reference.

Second compounds of the invention can be selected from phenanthroline or a derivative thereof as represented by Formula F: 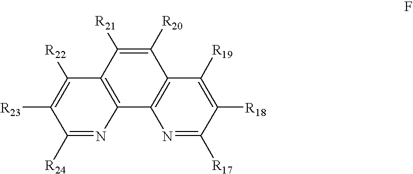
wherein

R₁₇, R₁₈, R₁₉, R₂₀, R₂₁, R₂₂, R₂₃ and R₂₄ are hydrogen or substituents; and

provided that any of the indicated substituents can join to form further fused rings.

Heterocyclic derivatives, represented by Formula G form a group of materials from which the second compounds of the invention can be selected: 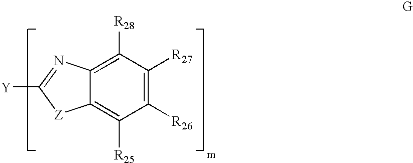
wherein

m is an integer of from 3 to 8;

Z is O, NR₂₉, or S;

R₂₅, R₂₆, R₂₇, R₂₈ and R₂₉ are hydrogen; alkyl of from 1 to 24 carbon atoms; aryl or hetero-atom substituted aryl of from 5 to 20 carbon atoms; or halo; or are the atoms necessary to complete a fused carbocyclic or heterocyclic ring; and

Y is a linkage unit usually comprising an alkyl or aryl group that conjugately or unconjugately connects the multiple benzazoles together.

Additional second compounds of the invention can be selected from silole or silacyclopentadiene derivatives represented by Formula H: 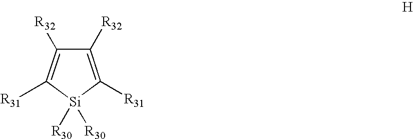
wherein

R₃₀, R₃₁, and R₃₂ are hydrogen or substituents or are the atoms necessary to complete a fused carbocyclic or heterocyclic ring.

Other second compounds of the invention can be selected from triazine derivatives represented by Formula I: 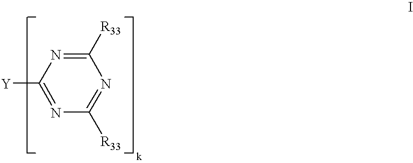
wherein

k is an integer of from 1 to 4;

R₃₃ is hydrogen, substituents or carbocyclic or heterocyclic rings; and

Y is a linkage unit usually comprising an alkyl or aryl group that conjugately or unconjugately connects the multiple triazines together.

At least one second compound in the further layer is a low-voltage electron-transporting compound. Furthermore, the second compound has a higher LUMO value than the polycyclic aromatic hydrocarbon compound. Specific second compounds based on formulae D, E, F, G, H, and I are shown in the following structures:

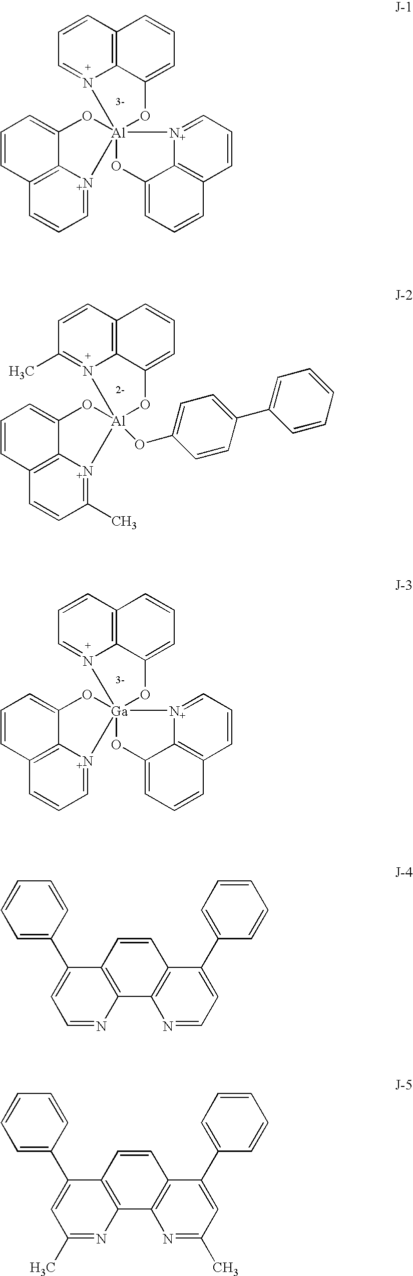

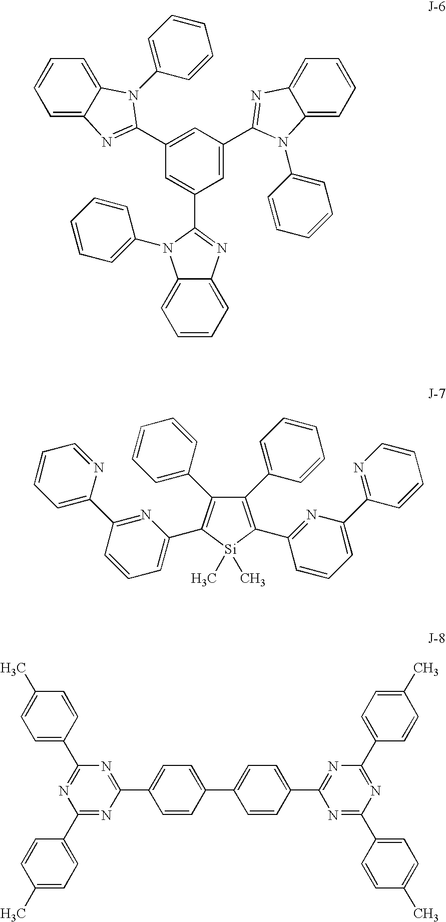

As used herein the term “metallic material” includes both the elemental metal and compounds thereof based on a metal having a work function less than 4.2 eV. The metallic material of said further layer is not restricted to a specific one, as long as it is a metal that can reduce at least one of the organic compounds. It can be selected from the alkali metals such as Li, alkaline earth metals such as Mg, and transition metals including rare earth metals. In particular, a metal having a work function of less than or equal to 4.2 eV can be suitably used as the metallic material, and typical examples of such metallic materials include Li, Na, K, Cs, Be, Mg, Ca, Sr, Ba, Y, La, Sm, Gd, Yb. Preferred metallic materials are Li and Cs.

The concentration of the metallic material in said further layer is not restricted to a specific one, but is in the range of from 0.1% to 15% by volume of the total material in the layer. The preferred concentration of metallic material is in the range of 0.1% to 10% but more preferably in the range of from 1% to 8%.

The amount of the polycyclic aromatic hydrocarbon compound in the layer is greater than or equal to 10% by volume of the layer but less than 100% by volume, and the total amount of the second compound(s) is less than or equal to 90% by volume of the layer but more than 0%. Particularly useful ranges for the polycyclic aromatic hydrocarbon compound are 20, 40, 50, 60, 75 and 90%, with 80, 60, 50, 40, 25 and 10%, respectively, for the total amounts for the second compound(s) and the metallic material. Embodiments of the invention are those in which the amount of the polycyclic aromatic hydrocarbon compound is selected from any value in the aforementioned range, the total amount of the second compound(s) is selected from any value in the aforementioned range and the amount of the metallic material is selected from the aforementioned range to fulfill the remainder, to 100%.

Preferred combinations of the invention are those wherein the polycyclic aromatic hydrocarbon compounds are selected from C-7, C-8, C-9, and C-11, and the second compounds are selected from J-1, J-2, J-3, J-4, and J-5.

As described, the further layer in the invention includes a polycyclic aromatic hydrocarbon compound, at least one second compound and a metal with a work function less than 4.2 eV. This combination in the further layer in the aforementioned ratios gives devices that have reduced drive voltages even lower when compared to the devices in which either the polycyclic aromatic hydrocarbon or second compound are incorporated alone in said layer.

Following are the chemical names and acronyms associated with compounds mentioned in the invention: C-1, rubrene, 5,6,11,12-tetraphenylnaphthacene; C-2, perylene; C-4,9-(2-naphthyl)-10-(4-phenyl)phenylanthracene; C-5, ADN, 9,10-bis(2-naphthyl)-anthracene; C-6, tBADN, 2-tert-butyl-9,10-bis(2-naphthyl)-anthracene; C-7, tBDPN, 5,12-bis[4-tert-butylphenyl]naphthacene; C-10, TBP, 2,5,8,11-tetra-tert-butylperylene; J-1, Alq or Alq₃, tris(8-quinolinolato)aluminum (III); J-2, BAlq; J-3, Gaq or Gaq₃, tris(8-quinolinolato)gallium(III); J-4, BPhen, 4,7-diphenyl-1,10-phenanthroline; J-5, BCP, 2,9-dimethyl-4,7-diphenyl-1,10-phenanthroline; J-6, TPBI, 2,2′,2″-1,3,5-tris[1-phenyl-1H-benzimidazol-2-yl]benzene; and J-8, TRAZ, 4,4′-bis(4,6-di-(p-tolyl)-1,3,5-triazin-2-yl)-1,1′-biphenyl.

For use herein, the term 8-quinolinolato ligand, is a ligand derived from 8-hydroxyquinoline wherein the nitrogen in the 1-position of quinoline coordinates, by donating its free pair of electrons to a metal or non-metal atom bound to the hydroxyl group in the 8-position, with the metal or non-metal atom accepting the electrons, to form a coordinate bond and a chelated or heterocyclic ring system. R^{S} is an 8-quinolinolato-ring substituent chosen to block sterically the attachment of more than two substituted 8-quinolinolato ligands to the metal or non-metal atom. Preferred R^{S} groups are selected from alkyl and aryl groups. L groups are hydrocarbons of from 6 to 24 carbon atoms. Preferred L groups are selected from alkyl, carbocyclic and heterocyclic groups. Y groups are selected from alkyl, carbocyclic or heterocyclic groups. Preferred Y groups are aryl or biphenyl groups. M can be any suitable metal or non-metal found in the periodic table that can be used to form compounds of Formulae D and E. For example, M can be an alkali metal, such as lithium, sodium, or potassium; an alkaline earth metal, such as magnesium or calcium; an earth metal, such as aluminum or gallium, or a transition metal such as zinc or zirconium. Generally any monovalent, divalent, trivalent, or tetravalent metals known to be a useful chelating metal can be employed. Also included are boron and beryllium.

The EL device of the invention is useful in any device where stable light emission is desired such as a lamp or a component in a static or motion imaging device, such as a television, cell phone, DVD player, or computer monitor. Typical embodiments of the invention provide not only improved drive voltage but can also provide improved luminance efficiency, operational stability and low voltage rise.

General Device Architecture

The present invention can be employed in most white-light-emitting OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with a thin film transistor (TFT).

There are numerous configurations of the organic layers wherein the present invention can be successfully practiced. As described, essential requirements are a cathode, an anode, one or more LELs, and a further layer. A more typical structure is shown in FIG. 1 for white light-emitting OLED device 100, and includes a substrate 110, an anode 120, an optional hole-injecting layer 130, a hole-transporting layer 132, a first light-emitting layer 134, a second light-emitting layer 135, an electron-transporting layer 136 (which in this embodiment is the further layer), an optional electron-injecting layer 138 and a cathode 140. These layers are described in detail below. Note that the substrate can alternatively be located adjacent to the cathode, or the substrate can actually constitute the anode or cathode. The total combined thickness of the organic layers is preferably less than 500 nm.

The light-emitting layer(s) can be constructed of a single layer, or multiple layers as shown. For white-light-emitting devices, generally two or more layers emitting different colors of light with sufficient spectral breadth are utilized so that when combined, white light is formed.

The anode and cathode of white-light-emitting OLED device 100 are connected to a voltage/current source 150 through electrical conductors 160. Applying a potential between anode 120 and cathode 140 such that the anode is at a more positive potential than the cathode operates the OLED device. Holes are injected into the organic EL element (that is, the layers between anode 120 and cathode 140) from the anode and electrons are injected from the cathode. Enhanced device stability can sometimes be achieved when the OLED device is operated in an AC mode where, for some time period in cycle, the potential bias is reversed and no current flows. An example of an AC-driven OLED device is described in U.S. Pat. No. 5,552,678.

Substrate

The substrate 110 can either be light transmissive or opaque, depending on the intended direction of light emission. The light transmissive property is desirable for viewing the EL emission through the substrate. Transparent glass or organic material are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials. Of course it is necessary to provide in these device configurations a light-transparent top electrode.

Anode

The conductive anode layer 120 is commonly formed over the substrate and, when EL emission is viewed through the anode, it should be transparent or substantially transparent to the emission of interest. Common transparent anode materials used in this invention are indium-tin oxide (ITO) and tin oxide, but other metal oxides can work including, but not limited to, aluminum- or indium-doped zinc oxide (IZO), magnesium-indium oxide, and nickel-tungsten oxide. In addition to these oxides, metal nitrides, such as gallium nitride, and metal selenides, such as zinc selenide, and metal sulfides, such as zinc sulfide, can be used in layer 120. For applications where EL emission is viewed through the top electrode, the transmissive characteristics of layer 120 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes.

Hole-Injecting Layer (HIL)

While not always necessary, it is often useful that a hole-injecting layer 130 be provided between anode 120 and hole-transporting layer 132. The hole-injecting material can serve to improve the film formation property of subsequent organic layers and to facilitate injection of holes into the hole-transporting layer. Suitable materials for use in the hole-injecting layer include, but are not limited to, porphyrinic compounds such as those described in U.S. Pat. No. 4,720,432, and plasma-deposited fluorocarbon polymers such as those described in U.S. Pat. No. 6,208,075. Alternative hole-injecting materials reportedly useful in organic EL devices are described in EP 0 891 121 A1 and EP 1 029 909 A1.

Hole-Transporting Layer (HTL)

The hole-transporting layer 132 of white-light-emitting OLED device 100 includes at least one hole-transporting compound such as an aromatic tertiary amine, where the latter is understood to be a compound containing at least one trivalent nitrogen atom that is bonded only to carbon atoms, at least one of which is a member of an aromatic ring. Additionally, the hole-transporting layer can be constructed of one or more layers such that each layer can be doped or un-doped with the same or different light-emitting material. The thickness of the HTL can be in the range of from 0.1 to 300 nm. In one form, the aromatic tertiary amine can be an arylamine, such as a monoarylamine, diarylamine, triarylamine, or a polymeric arylamine group. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula K. 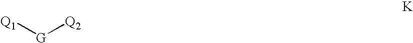
wherein Q₁ and Q₂ are independently selected aromatic tertiary amine moieties and G is a linking group such as an arylene, cycloalkylene, or alkylene group of a carbon to carbon bond. In one embodiment, at least one of Q₁, or Q₂ contains a polycyclic fused ring group, e.g., a naphthalene. When G is an aryl group, it is conveniently a phenylene, biphenylene, or naphthalene group.

A useful class of triarylamine groups satisfying structural formula K and containing two triarylamine groups is represented by structural formula L: 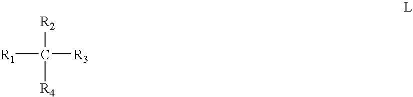
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula M: 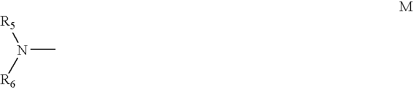
wherein R₅ and R₆ are independently selected aryl groups. In one embodiment, at least one of R₅ or R₆ contains a polycyclic fused ring group, e.g., a naphthalene.

Another class of aromatic tertiary amine groups are the tetraaryldiamines. Desirable tetraaryldiamines groups include two diarylamino groups, such as indicated by formula M, linked through an arylene group. Useful tetraaryldiamines include those represented by formula N. 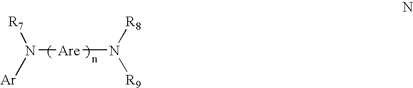
wherein

each Are is an independently selected arylene group, such as a phenylene or anthracene group,

n is an integer of from 1 to 4, and

Ar, R₇, R₈, and R₉ are independently selected aryl groups.

In a typical embodiment, at least one of Ar, R₇, R₈, and R₉ is a polycyclic fused ring group, e.g., a naphthalene

The various alkyl, alkylene, aryl, and arylene groups of the foregoing structural formulae K, L, M, and N, can each in turn be substituted. Typical substituents include alkyl groups, alkoxy groups, aryl groups, aryloxy groups, and halogen such as fluoride, chloride, and bromide. The various alkyl and alkylene groups typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene groups are usually phenyl and phenylene moieties.

Hole-transporting layer 132 can be formed of a single or a mixture of aromatic tertiary amine compounds. Specifically, one can employ a triarylamine, such as a triarylamine satisfying the formula L, in combination with a tetraaryldiamine, such as indicated by formula N. When a triarylamine is employed in combination with a tetraaryldiamine, the latter is positioned as a layer interposed between the triarylamine and the electron-injecting and transporting layers. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl(NPB)
4,4′-Bis[N-(1-naphthyl)-N-(2-naphthyl)amino]biphenyl(TNB)
4,4″-Bis[N-(1-naphthyl)-N-phenylamino]-p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine (MTDATA)
4,4′-Bis[N-(3-methylphenyl)-N-phenylamino]biphenyl (TPD)

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layers (LEL)

White-light-emitting OLED device 100 includes one or more light-emitting layers to produce white light. In this embodiment, first and second light-emitting layers 134 and 135, respectively, produce light in response to hole-electron recombination and are commonly disposed over hole-transporting layer 132, although hole-transporting layer 132 is not required for the practice of this invention. Useful organic light-emitting materials are well known. As more fully described in U.S. Pat. Nos. 4,769,292 and 5,935,721, each of the light-emitting layers of the organic EL element includes a luminescent or fluorescent material where electroluminescence is produced as a result of electron-hole pair recombination in this region. While light-emitting layers can be comprised of a single material, they more commonly include a host material doped with a guest compound or dopant where light emission comes primarily from the dopant. The non-electroluminescent compound or compounds in the light-emitting layers can be an electron-transporting material, as defined below, a hole-transporting material, as defined above, or another material or combination of materials that support hole-electron recombination. The electroluminescent compounds are usually chosen from highly fluorescent dyes, but phosphorescent compounds, e.g., transition metal complexes as described in WO 98/55561, WO 00/18851, WO 00/57676, and WO 00/70655 are also useful. Electroluminescent compounds can be coated as 0.01 to 50% into the non-electroluminescent component material, but typically coated as 0.01 to 30% and more typically coated as 0.01 to 15% into the non-electroluminescent component. The thickness of the LEL can be any suitable thickness. It can be in the range of from 0.1 mm to 100 mm.

Non-electroluminescent compounds and emitting molecules known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (as in Formula D, above) constitute one class of useful non-electroluminescent component compounds capable of supporting electroluminescence, and are particularly suitable for light emission of wavelengths longer than 500 nm, e.g., green, yellow, orange, and red. The metal M can be a monovalent, divalent, trivalent, or tetravalent metal. The metal can, for example, be an alkali metal, such as lithium, sodium, or potassium; an alkaline earth metal, such as magnesium or calcium; an earth metal, such as aluminum or gallium, or a transition metal such as zinc or zirconium. Generally any monovalent, divalent, trivalent, or tetravalent metal known to be a useful chelating metal can be employed. Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)] (B-1)
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)] (B-3)
CO-9: Zirconium oxine [alias, tetra(8-quinolinolato)zirconium(IV)]
CO-10: Bis(2-methyl-8-quinolinato)-4-phenylphenolatoaluminum (III)

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

A preferred embodiment of the luminescent layer consists of a host material doped with fluorescent dyes. Using this method, highly efficient EL devices can be constructed. Simultaneously, the color of the EL devices can be tuned by using fluorescent dyes of different emission wavelengths in a common host material. Tang et al. in commonly assigned U.S. Pat. No. 4,769,292 has described this dopant scheme in considerable details for EL devices using Alq as the host material.

Shi et al. in commonly assigned U.S. Pat. No. 5,935,721 has described this dopant scheme in considerable details for the blue emitting OLED devices using 9,10-di-(2-naphthyl)anthracene (ADN) derivatives as the host material.

Derivatives of 9,10-di-(2-naphthyl)anthracene (Formula P) constitute one class of useful non-electroluminescent compounds capable of supporting electroluminescence, and are particularly suitable for light emission of wavelengths longer than 400 nm, e.g., blue, green, yellow, orange or red. 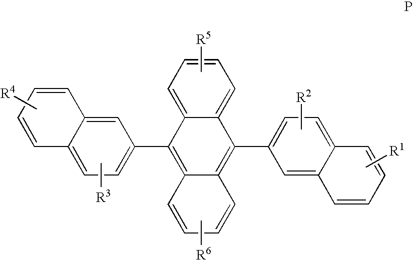
wherein: R¹, R², R³, R⁴, R⁵, and R⁶ represent hydrogen or one or more substituents selected from the following groups:

Group 1: hydrogen, alkyl and alkoxy groups typically having from 1 to 24 carbon atoms;

Group 2: a ring group, typically having from 6 to 20 carbon atoms;

Group 3: the atoms necessary to complete a carbocyclic fused ring group such as naphthyl, anthracenyl, pyrenyl, and perylenyl groups, typically having from 6 to 30 carbon atoms;

Group 4: the atoms necessary to complete a heterocyclic fused ring group such as furyl, thienyl, pyridyl, and quinolinyl groups, typically having from 5 to 24 carbon atoms;

Group 5: an alkoxylamino, alkylamino, and arylamino group typically having from 1 to 24 carbon atoms; and

Group 6: fluorine, chlorine, bromine and cyano radicals.

Illustrative examples include 9,10-di-(2-naphthyl)anthracene (ADN) and 2-t-butyl-9,10-di-(2-naphthyl)anthracene (TBADN). Other anthracene derivatives can be useful as an non-electroluminescent compound in the LEL, such as diphenylanthracene and its derivatives, as described in U.S. Pat. No. 5,927,247. Styrylarylene derivatives as described in U.S. Pat. No. 5,121,029 and JP 08333569 are also useful non-electroluminescent materials for blue emission. For example, 9,10-bis[4-(2,2-diphenylethenyl)phenyl]anthracene, 4,4′-bis(2,2-diphenylethenyl)-1,1′-biphenyl (DPVBi) and phenylanthracene derivatives as described in EP 681,019 are useful non-electroluminescent materials for blue emission. Another useful non-electroluminescent material capable of supporting electroluminescence for blue-light emission is C-4, shown above, and its derivatives.

Benzazole derivatives (Formula Q) constitute another class of useful non-electroluminescent components capable of supporting electroluminescence, and are particularly suitable for light emission of wavelengths longer than 400 nm, e.g., blue, green, yellow, orange or red. 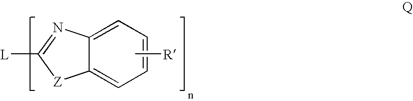
where:

n is an integer of 3 to 8;

Z is −O, —NR or —S where R is H or a substituent;

R′ represents one or more optional substituents where R and each R′ are H or alkyl groups such as propyl, t-butyl, and heptyl groups typically having from 1 to 24 carbon atoms; carbocyclic or heterocyclic ring groups such as phenyl and naphthyl, furyl, thienyl, pyridyl, and quinolinyl groups and atoms necessary to complete a fused aromatic ring group typically having from 5 to 20 carbon atoms; and halo such as chloro, and fluoro; and

L is a linkage unit usually comprising an alkyl or aryl group which conjugately or unconjugately connects the multiple benzazoles together.

An example of a useful benzazole is 2,2′,2″-(1,3,5-benzenetriyl)tris[1-phenyl-1H-benzimidazole], (TPBI).

Distyrylarylene derivatives as described in U.S. Pat. No. 5,121,029 are also useful non-electroluminescent component materials in the LEL.

Desirable fluorescent dopants for OLED devices can include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds. Illustrative examples of useful dopants include, but are not limited to, the following:

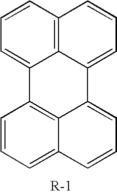

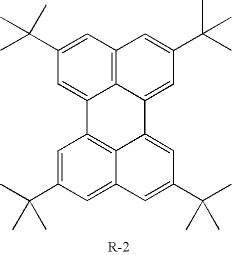

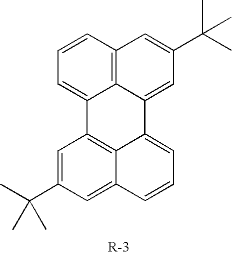

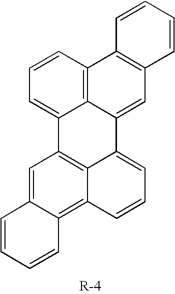

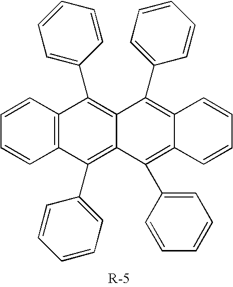

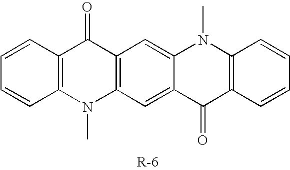

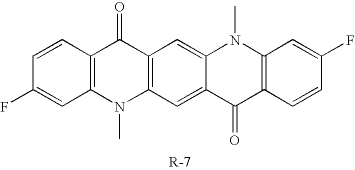

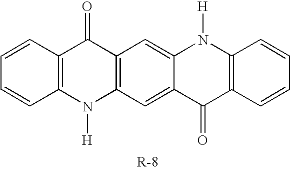

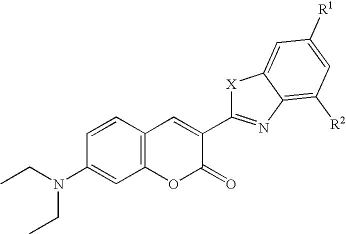

| | X | R1 | R2 |
|---|---|---|---|
| R-9 | O | H | H |
| R-10 | O | H | Methyl |
| R-11 | O | Methyl | H |
| R-12 | O | Methyl | Methyl |
| R-13 | O | H | t-butyl |
| R-14 | O | t-butyl | H |
| R-15 | O | t-butyl | t-butyl |
| R-16 | S | H | H |
| R-17 | S | H | Methyl |
| R-18 | S | Methyl | H |
| R-19 | S | Methyl | Methyl |
| R-20 | S | H | t-butyl |
| R-21 | S | t-butyl | H |
| R-22 | S | t-butyl | t-butyl |
| 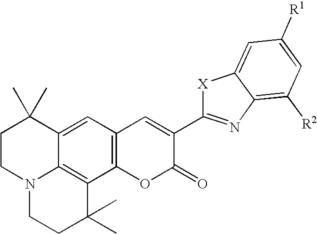 | | | |
| | X | R1 | R2 |
| R-23 | O | H | H |
| R-24 | O | H | Methyl |
| R-25 | O | Methyl | H |
| R-26 | O | Methyl | Methyl |
| R-27 | O | H | t-butyl |
| R-28 | O | t-butyl | H |
| R-29 | O | t-butyl | t-butyl |
| R-30 | S | H | H |
| R-31 | S | H | Methyl |
| R-32 | S | Methyl | H |
| R-33 | S | Methyl | Methyl |
| R-34 | S | H | t-butyl |
| R-35 | S | t-butyl | H |
| R-36 | S | t-butyl | t-butyl |

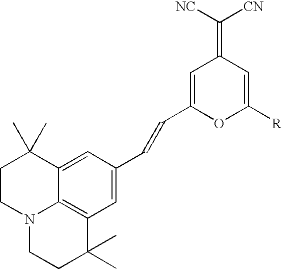

| | R |
|---|---|
| R-37 | phenyl |
| R-38 | methyl |
| R-39 | t-butyl |
| R-40 | mesityl |
| 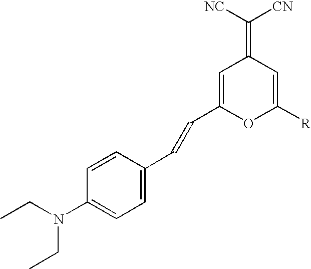 | |
| | R |
| R-41 | phenyl |
| R-42 | methyl |
| R-43 | t-butyl |
| R-44 | mesityl |

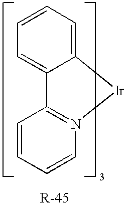

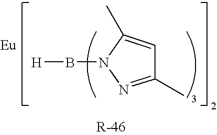

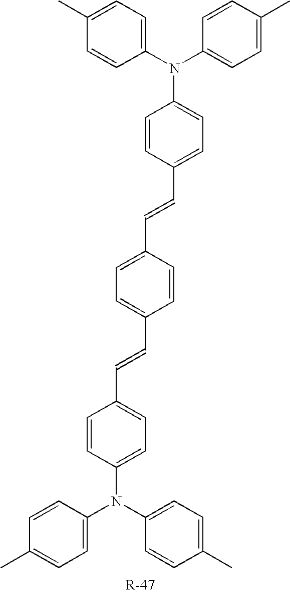

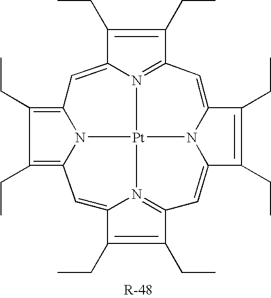

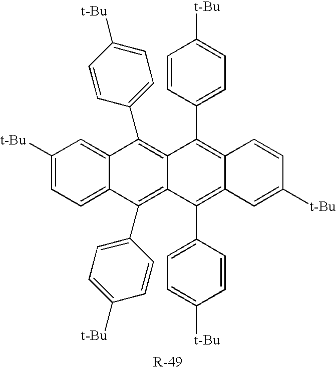

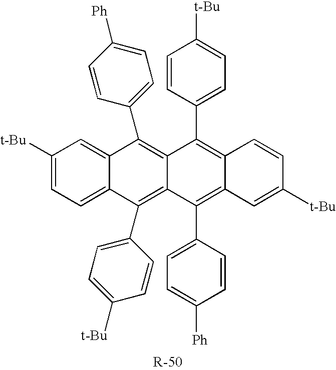

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119B1 and references cited therein.

An important relationship for choosing a dye as a dopant is a comparison of the bandgap potential which is defined as the energy difference between the highest occupied molecular orbital and the lowest unoccupied molecular orbital of the molecule. For efficient energy transfer from the host material to the dopant molecule, a necessary condition is that the band gap of the dopant is smaller than that of the host material.

Emitting molecules known to be of use include, but are not limited to, those disclosed in U.S. Pat. Nos. 4,768,292; 5,141,671; 5,150,006; 5,151,629; 5,294,870; 5,405,709; 5,484,922; 5,593,788; 5,645,948; 5,683,823; 5,755,999; 5,928,802; 5,935,720; 5,935,721; 6,020,078; and 6,534,199.

It is a feature of this invention that the OLED device produce white light, and therefore the combined emissions of light-emitting materials be white. Those skilled in the art will understand that a wide variety of methods can be used, and that this invention is not restricted to those examples herein. While examples are known wherein a single light-emitting layer in an OLED device produces white light, it is more common to use two or more layers with complementary emission spectra to produce a combined white emission.

The light-emitting layers include a host material and one or more light-emitting materials. The host material can be a mixture of one or more mono-anthracene derivatives provided in a volume fraction range of 5% to 50% relative to the total host volume, and one or more aromatic amine derivatives provided in a volume fraction range of 50% to 95% relative to the total host volume.

The mono-anthracene derivative(s) can be derivatives of a single anthracene nucleus having hydrocarbon or substituted hydrocarbon substituents at the 9 and 10 positions, for example, derivatives of 9,10-di-(2-naphthyl) anthracene (Formula C-5, above). The mono-anthracene derivative of Formula S is also a useful host material capable of supporting electroluminescence, and is particularly suitable for light emission of wavelengths longer than 400 nm, e.g., blue, green, yellow, orange or red. Mono-anthracene derivatives of Formula S are described in commonly assigned U.S. patent application Ser. No. 10/693,121 filed Oct. 24, 2003 by Lelia Cosimbescu et al., entitled “Electroluminescent Device With Anthracene Derivative Host” and commonly assigned U.S. patent application Ser. No. 11/076,720 filed Mar. 10, 2005 by Scott R. Conley et al., entitled “Organic Electroluminescent Device”, the disclosures of which are herein incorporated by reference, 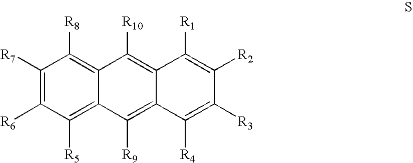
wherein:

R₁-R₈ are H; and

R₉ is a naphthyl group containing no fused rings with aliphatic carbon ring members; provided that R₉ and R₁₀ are not the same, and are free of amines and sulfur compounds. Suitably, R₉ is a substituted naphthyl group with one or more further fused rings such that it forms a fused aromatic ring system, including a phenanthryl, pyrenyl, fluoranthene, perylene, or substituted with one or more substituents including fluorine, cyano group, hydroxy, alkyl, alkoxy, aryloxy, aryl, a heterocyclic oxy group, carboxy, trimethylsilyl group, or an unsubstituted naphthyl group of two fused rings. Conveniently, R₉ is 2-naphthyl, or 1-naphthyl substituted or unsubstituted in the para position; and

R₁₀ is a biphenyl group having no fused rings with aliphatic carbon ring members. Suitably R₁₀ is a substituted biphenyl group, such that is forms a fused aromatic ring system including but not limited to a naphthyl, phenanthryl, perylene, or substituted with one or more substituents including fluorine, cyano group, hydroxy, alkyl, alkoxy, aryloxy, aryl, a heterocyclic oxy group, carboxy, trimethylsilyl group, or an unsubstituted biphenyl group. Conveniently, R₁₀ is 4-biphenyl, 3-biphenyl unsubstituted or substituted with another phenyl ring without fused rings to form a terphenyl ring system, or 2-biphenyl. Particularly useful is 9-(2-naphthyl)-10-(4-biphenyl)anthracene.

Some examples of useful mono-anthracene materials for use in a light-emitting layer include:

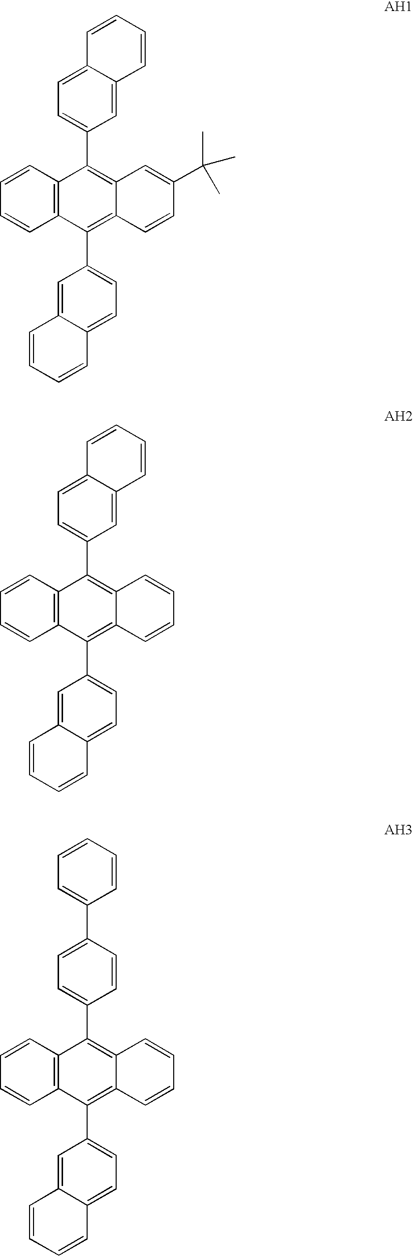

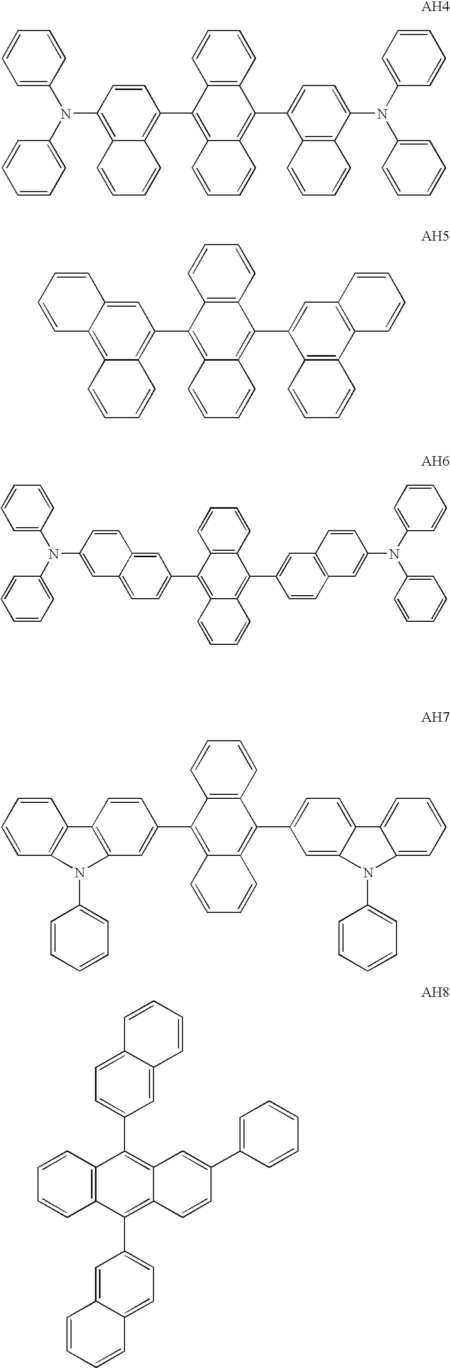

The first light-emitting layer 134 is disposed over hole-transporting layer 132 and includes a first light-emitting material. In a preferred embodiment, first light-emitting layer 134 can be a yellow, orange, or red-light-emitting layer with a peak emission in the yellow to red portion of the visible spectrum, and therefore it is doped with a first light-emitting material that can be a light-emitting yellow, orange, or red dopant. The light-emitting yellow dopant can include a compound of the following structures: 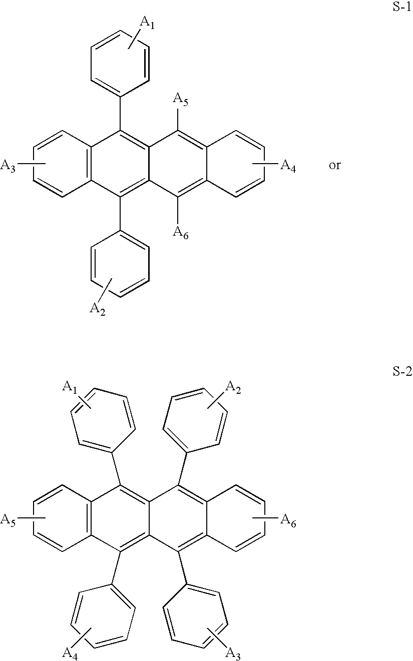
wherein A₁-A₆ represent one or more substituents on each ring and where each substituent is individually selected from one of the following:
Category 1: hydrogen, or alkyl of from 1 to 24 carbon atoms;
Category 2: aryl or substituted aryl of from 5 to 20 carbon atoms;
Category 3: hydrocarbon containing 4 to 24 carbon atoms, completing a fused aromatic ring or ring system;
Category 4: heteroaryl or substituted heteroaryl of from 5 to 24 carbon atoms such as thiazolyl, furyl, thienyl, pyridyl, quinolinyl or other heterocyclic systems, which are bonded via a single bond, or complete a fused heteroaromatic ring system;
Category 5: alkoxylamino, alkylamino, or arylamino of from 1 to 24 carbon atoms; or
Category 6: fluoro, chloro, bromo or cyano.

Examples of particularly useful yellow dopants include 5,6,11,12-tetraphenylnaphthacene (rubrene); 6,11-diphenyl-5,12-bis(4-(6-methyl-benzothiazol-2-yl)phenyl)naphthacene (DBzR) and 5,6,11,12-tetra(2-naphthyl)naphthacene (NR), the formulas of which are shown below:

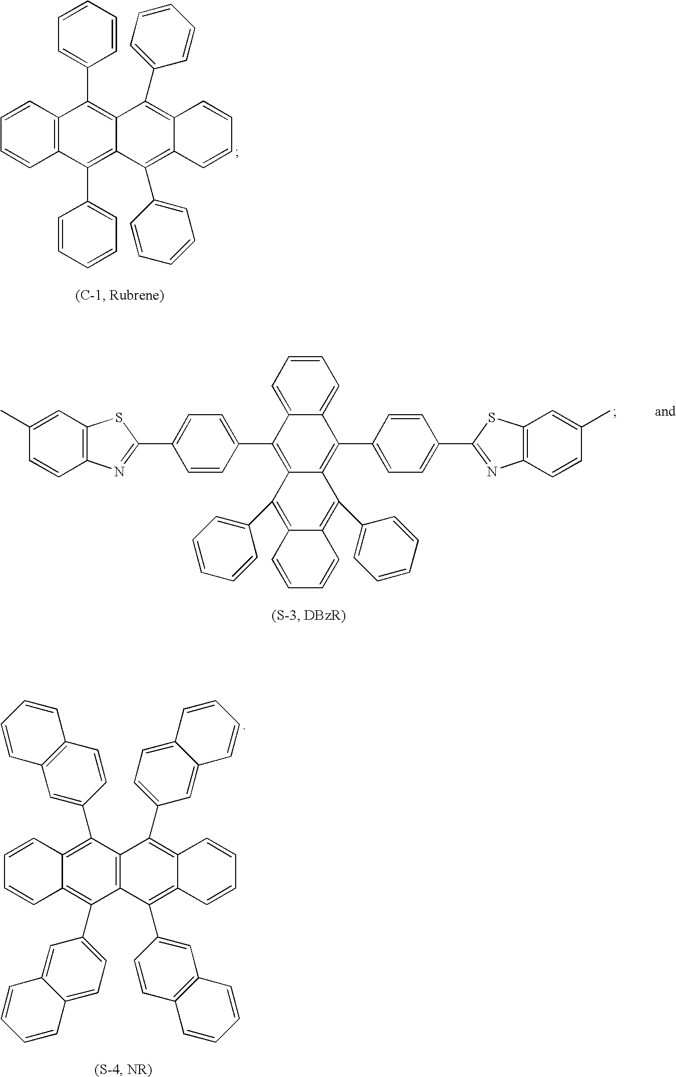

The yellow dopant can also be a mixture of compounds that would also be yellow dopants individually.

The light-emitting red dopant can include a diindenoperylene compound of the following structure T-1: 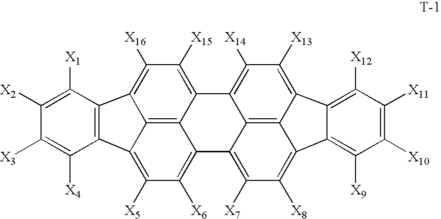
wherein:
X₁-X₁₆ are independently selected as hydro or substituents that provide red luminescence.

Illustrative examples of useful red dopants of this class include the following:

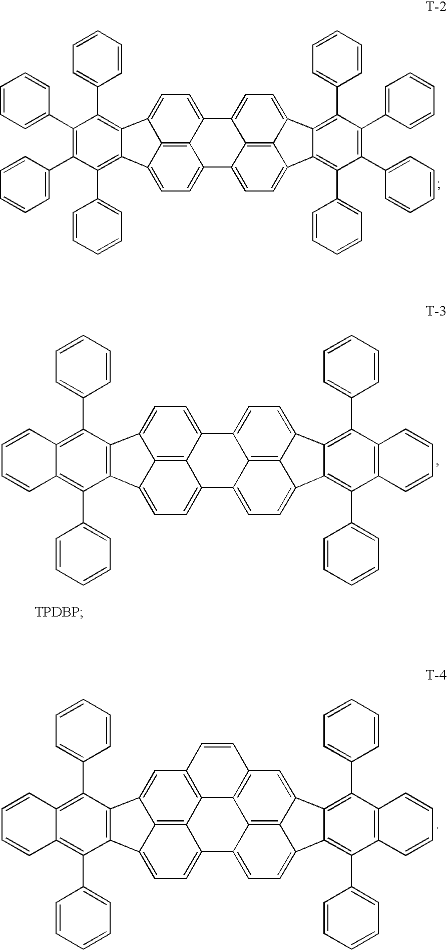

A particularly preferred diindenoperylene dopant is dibenzo{[f,f′]-4,4′7,7′-tetraphenyl]diindeno-[1,2,3-cd:1′,2′,3′-lm]perylene (TPDBP, T-3 above).

Other red dopants useful in the present invention belong to the DCM class of dyes represented by Formula V-1: 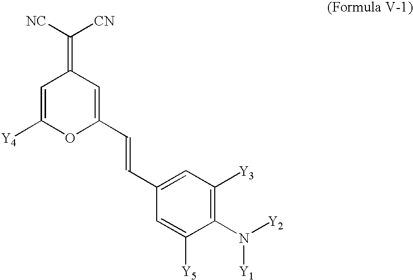
wherein Y₁-Y₅ represent one or more groups independently selected from: hydro, alkyl, substituted alkyl, aryl, or substituted aryl; Y₁-Y₅ independently include acyclic groups or are joined pairwise to form one or more fused rings; provided that Y₃ and Y₅ do not together form a fused ring.

In a useful and convenient embodiment that provides red luminescence, Y₁-Y₅ are selected independently from: hydro, alkyl and aryl. Structures of particularly useful dopants of the DCM class are shown below:

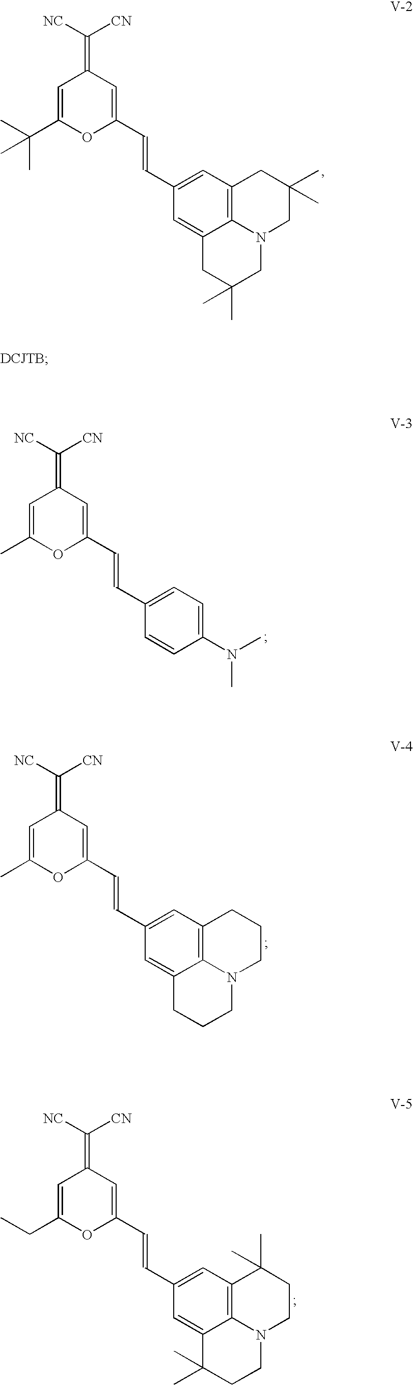

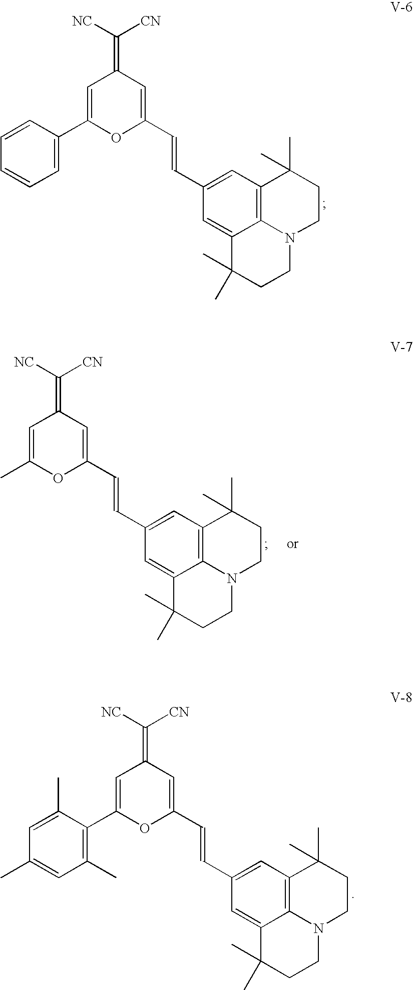

A preferred DCM dopant is DCJTB. The red dopant can also be a mixture of compounds that would also be red dopants individually.

Second light-emitting layer 135 is disposed directly on or under first light-emitting layer 134. Second light-emitting layer 135 has a peak emission in the blue to blue-green portion of the spectrum, so that white light is produced by the combined emission of the two light-emitting layers. Second light-emitting layer 135 includes a second host material and a second light-emitting material. The second host material can be the same as above, or can be different. In one embodiment, the second host material is one or more mono-anthracene derivatives, wherein the mono-anthracene derivatives are selected from the same potential mono-anthracene derivatives as for first light-emitting layer 134. The mono-anthracene derivative(s) selected for second light-emitting layer 135 can be the same as or different from those selected for first light-emitting layer 134.

In another embodiment, the second host material can include a mixture of one or more mono-anthracene derivatives provided in a volume fraction range of greater than 85% to less than 100% relative to the total host volume, and one or more aromatic amine derivatives provided in a volume fraction range of greater than 0% to less than 15% relative to the total host volume. The mono-anthracene derivatives are selected from the same mono-anthracene derivative candidates, and the aromatic amine derivatives from the same aromatic amine derivative candidates, as for first light-emitting layer 134. The mono-anthracene derivative(s) selected for second light-emitting layer 135 can be the same as or different from those selected for first light-emitting layer 134. Likewise, the aromatic amine derivative(s) selected for second light-emitting layer 135 can be the same as or different from those selected for first light-emitting layer 134.

The second light-emitting material can be a light-emitting blue or blue-green dopant and can include perylene or derivatives thereof, blue-emitting derivatives of distyrylbenzene or a distyrylbiphenyl that have one or more aryl amine substitutents, or a compound of the structure W-1, known as a bis(azinyl)amine borane complex, and is described in commonly assigned U.S. Pat. No. 6,661,023 (Feb. 9, 2003) by Benjamin P. Hoag et al., entitled “Organic Element for Electroluminescent Devices”; the disclosure of which is incorporated herein. 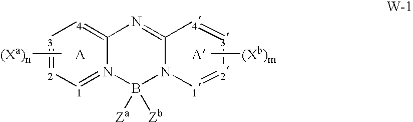
wherein:
A and A′ represent independent azine ring systems corresponding to 6-membered aromatic ring systems containing at least one nitrogen;
(X^{a})ₙ and (X^{b})ₘ represent one or more independently selected substituents and include acyclic substituents or are joined to form a ring fused to A or A′;
m and n are independently 0 to 4;
Z^{a} and Z^{b} are independently selected substituents;
1, 2, 3, 4, 1′, 2′, 3′, and 4′ are independently selected as either carbon or nitrogen atoms; and
provided that X^{a}, X^{b}, Z^{a}, and Z^{b}, 1, 2, 3, 4, 1′, 2′, 3′, and 4′ are selected to provide blue luminescence.

Some examples of the above class of dopants include the following:

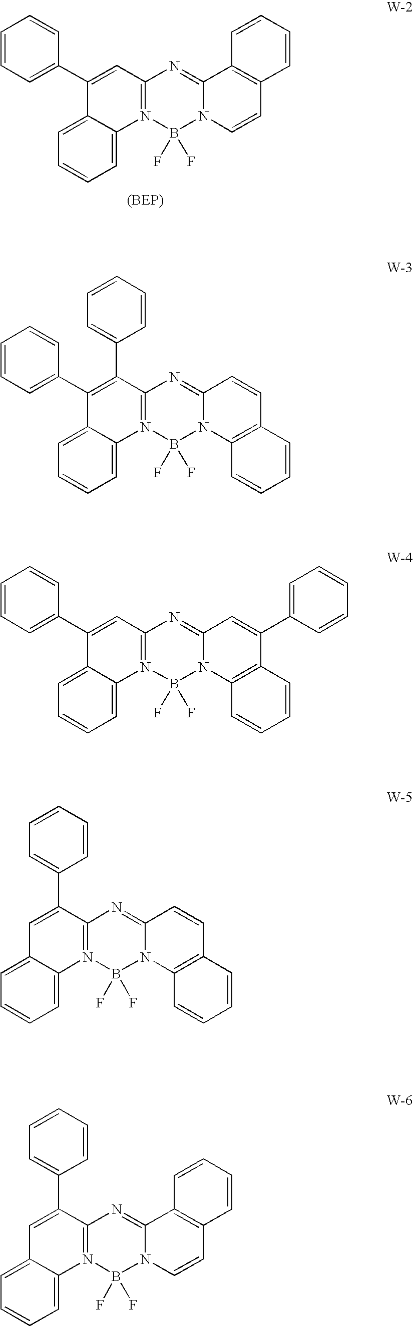

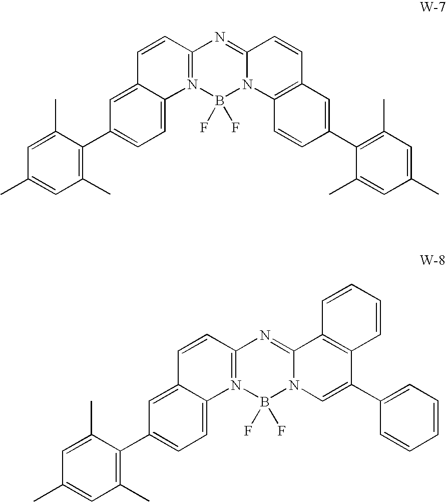

Another particularly useful class of blue dopants includes blue-emitting derivatives of such distyrylarenes as distyrylbenzene and distyrylbiphenyl, including compounds described in U.S. Pat. No. 5,121,029. Among derivatives of distyrylarenes that provide blue luminescence, particularly useful are those substituted with diarylamino groups, also known as distyrylamines. Examples include bis[2-[4-[N,N-diarylamino]phenyl]vinyl]-benzenes of the general structure X-1 shown below: 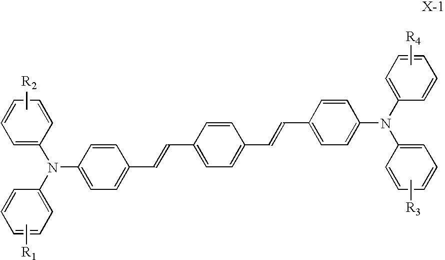
and bis[2-[4-[N,N-diarylamino]phenyl]vinyl]biphenyls of the general structure X-2 shown below:

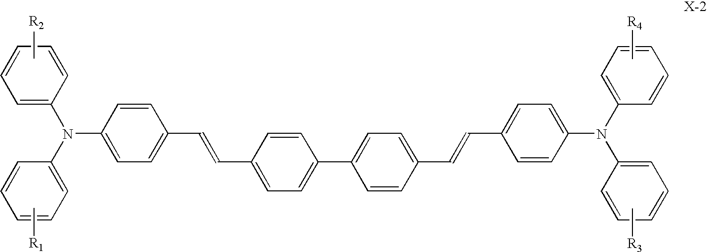

In Formulas X-1 and X-2, R₁-R₄ can be the same or different, and individually represent one or more substituents such as alkyl, aryl, fused aryl, halo, or cyaNo. In a preferred embodiment, R₁-R₄ are individually alkyl groups, each containing from one to about ten carbon atoms. A particularly preferred blue dopant of this class is 1,4-bis[2-[4-[N,N-di(p-tolyl)amino]phenyl]vinyl]benzene (BDTAPVB, Formula R-47 above).

Blue or blue-green dopants or light-emitting materials can be coated as 0.01 to 50% by weight into the host material, but typically coated as 0.01 to 30% and more typically coated as 0.01 to 15% by weight into the host material. The thickness of the blue-light emitting layer can be any suitable thickness. It can be in the range of from 10 to 100 nm.

Electron-Transporting Layer (ETL)

Although the electron-transporting layer 136 is the further layer of the invention whose nature has been described, it is possible to include other electron-transporting layers in the device. Preferred thin film-forming materials for use in forming such electron-transporting layers are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula D, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural formula G are also useful electron transporting materials.

Cathode

When light emission is through anode 120, cathode 140 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. Cathode materials are comprised of Mg:Ag, Al:Li and Mg:Al alloys. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of Al as described in U.S. Pat. No. 5,677,572. Other useful cathode materials include, but are not limited to, those disclosed in U.S. Pat. Nos. 5,059,861; 5,059,862; and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Deposition of Organic Layers

The organic materials mentioned above are suitably deposited through sublimation, but can be deposited from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,851,709 and U.S. Pat. No. 6,066,357) and inkjet method (U.S. Pat. No. 6,066,357).

Organic materials useful in making OLEDs, for example organic hole-transporting materials, organic light-emitting materials doped with an organic electroluminescent components have relatively complex molecular structures with relatively weak molecular bonding forces, so that care must be taken to avoid decomposition of the organic material(s) during physical vapor deposition. The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic material, the vapor condensing on a substrate to provide an organic layer thereon.

Several problems have been observed in using organic powders, flakes, or granules in physical vapor deposition: These powders, flakes, or granules are difficult to handle. These organic materials generally have a relatively low physical density and undesirably low thermal conductivity, particularly when placed in a physical vapor deposition source which is disposed in a chamber evacuated to a reduced pressure as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; This can lead to nonuniform heating of such organic materials in physical vapor deposition sources. Therefore, result in potentially nonuniform vapor-deposited organic layers formed on a substrate.

These organic powders can be consolidating into a solid pellet. These solid pellets consolidating into a solid pellet from a mixture of a sublimable organic material powder are easier to handle. Consolidation of organic powder into a solid pellet can be accomplished with relatively simple tools. A solid pellet formed from mixture comprising one or more non-luminescent organic non-electroluminescent component materials or luminescent electroluminescent component materials or mixture of non-electroluminescent component and electroluminescent component materials can be placed into a physical vapor deposition source for making organic layer. Such consolidated pellets can be used in a physical vapor deposition apparatus.

In one aspect, the present invention provides a method of making an organic layer from compacted pellets of organic materials on a substrate, which will form part of an OLED.

One preferred method for depositing the materials of the present invention is described in US Publication No. 2004/0255857 and U.S. application Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned U.S. patent application Ser. Nos. 10/784,585; 10/805,980; 10/945,940; 10/945,941; 11/050,924; and 11/050,934. Using this second method, each material can be evaporated using different source evaporators or the solid materials can be mixed prior to evaporation using the same source evaporator.

Encapsulation

Most OLED devices are sensitive to moisture and/or oxygen so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890.

The invention and its advantages are further illustrated by the specific examples that follow. The term “percentage” or “percent” and the symbol “%” indicate the volume percent (or a thickness ratio as measured on a thin film thickness monitor) of a particular first or second compound of the total material in the layer of the invention and other components of the devices. If more than one second compound is present, the total volume of the second compounds can also be expressed as a percentage of the total material in the layer of the invention.

### EXAMPLES

The invention and its advantages can be better appreciated by the following inventive and comparative examples.

### Example 1 (Comparative)

A comparative OLED device was constructed in the following manner:
1. A clean glass substrate was vacuum-deposited with indium tin oxide (ITO) to form a transparent electrode of 20 nm thickness;
2. The above-prepared ITO surface was treated with a plasma oxygen etch, followed by plasma deposition of a 0.5 nm layer of a fluorocarbon polymer (CFx) as described in U.S. Pat. No. 6,208,075;
3. The above-prepared substrate was further treated by vacuum-depositing a 60 nm layer of 4,4′-bis[N-(1-naphthyl)-N-phenylamino]biphenyl (NPB) as a hole-transporting layer (HTL);
4. A 20 nm layer of NPB (as host) with 20% 9-(2-naphthyl)-10-(biphenyl-4-yl)anthracene (Compound AH3, above) and 3% 5,11-bis(biphenyl-4-yl)-6,12-bis(4-tert-butylphenyl)-3,9-di-tert-butylnaphthacene (Compound C-8, above) was vacuum-deposited onto the substrate at a coating station that included a heated graphite boat source to form a yellow-light-emitting layer (yellow LEL);
5. A coating of 20 nm of Compound AH3 as host with 7% NPB and 1% 2,5,8,11-tetra-tert-butylperylene (TBP, C-10) was evaporatively deposited on the above substrate to form a blue light-emitting layer (blue LEL);
6. A 25 nm layer of tris(8-quinolinolato)aluminum (III) (ALQ) doped with 2.5% lithium metal was vacuum-deposited onto the substrate at a coating station that included a heated graphite boat source to form an electron-transporting layer; and
7. A 200 nm aluminum cathode layer was deposited onto the electron-transporting layer at a coating station with a tantalum boat.
8. The device was then transferred to a dry box for encapsulation.

### Example 2 (Comparative)

A comparative OLED device was constructed as in Example 1, except that in step 6 the layer was a 50:50 mixture of ALQ and 4,7-diphenyl-1,10-phenanthroline (Bphen, J-4) doped with 2.5% lithium metal.

### Example 3 (Comparative)

A comparative OLED device was constructed as in Example 1, except that in step 6 the layer was a 50:50 mixture of BPhen and Compound C-8.

### Example 4 (Inventive)

An inventive OLED device was constructed as in Example 1, except that in step 6 the layer was a 50:50 mixture of BPhen and Compound C-8 doped with 1% lithium metal.

### Example 5 (Inventive)

An inventive OLED device was constructed as in Example 1, except that in step 6 the layer was a 50:50 mixture of BPhen and Compound C-8 doped with 2% lithium metal.

Results (Examples 1-5)

The devices were tested by applying a current across the electrodes of 20 mA/cm² and measuring the spectrum and required drive voltage. The relative luminous efficiency is defined as the luminous efficiency of the example device, in cd/A, divided by the luminous efficiency in, cd/A, of reference Example 1. The CIE change magnitude is the magnitude of the color change in CIE color space relative to reference Example 1. The following table shows the results.

TABLE 1

| | Example: | | | | |
|---|---|---|---|---|---|
| | 1 | 2 | 3 | 4 | 5 |
| Type | Comp | Comp | Comp | Inv | Inv |
| (Inventive or Comparative) | | | | | |
| Drive voltage at 20 mA/cm² | 5.80 | 4.40 | 6.40 | 4.40 | 4.50 |
| Relative Drive voltage | 1.00 | 0.76 | 1.10 | 0.76 | 0.78 |
| Yield (cd/A) | 8.90 | 11.50 | 5.06 | 10.70 | 9.93 |
| Relative Luminous Efficiency | 1.00 | 1.29 | 0.57 | 1.20 | 1.12 |
| CIE x | 0.31 | 0.37 | 0.32 | 0.34 | 0.34 |
| CIE y | 0.33 | 0.38 | 0.33 | 0.35 | 0.35 |
| CIE change magnitude | — | 0.08 | 0.01 | 0.04 | 0.04 |

LUMO Values.

An important relationship exists when selecting the first compound(s) and second compound(s) of the invention. A comparison of the LUMO values of the first and second compounds in the layer of the invention, must be carefully considered. In devices of the invention, for there to be a drive voltage reduction over devices that contain only a first compound or only a second compound, there must be a difference in the LUMO values of the compounds. The first compound must have a lower LUMO value (more negative) than the second compound, or compounds (less negative).

The LUMO values are typically determined experimentally by electrochemical methods. A Model CHI660 electrochemical analyzer (CH Instruments, Inc., Austin, Tex.) was employed to carry out the electrochemical measurements. Cyclic voltammetry (CV) and Osteryoung square-wave voltammetry (SWV) were used to characterize the redox properties of the compounds of interest. A glassy carbon (GC) disk electrode (A=0.071 cm²) was used as working electrode. The GC electrode was polished with 0.05 um alumina slurry, followed by sonication cleaning in Milli-Q deionized water twice and rinsed with acetone in between water cleaning. The electrode was finally cleaned and activated by electrochemical treatment prior to use. A platinum wire served as counter electrode and a saturated calomel electrode (SCE) was used as a quasi-reference electrode to complete a standard 3-electrode electrochemical cell. Ferrocene (Fc) was used as an internal standard (E_{Fc}=0.50 V vs. SCE in 1:1 acetonitrile/toluene, 0.1 M TBAF). Mixture of acetonitrile and toluene (50%/50% v/v, or 1:1) was used as organic solvent system. The supporting electrolyte, tetrabutylammonium tetraflouroborate (TBAF) was recrystallized twice in isopropanol and dried under vacuum. All solvents used were low water grade (<20 ppm water). The testing solution was purged with high purity nitrogen gas for approximately 5 minutes to remove oxygen and a nitrogen blanket was kept on the top of the solution during the course of the experiments. All measurements were performed at ambient temperature of 25±1° C. The oxidation and reduction potentials were determined either by averaging the anodic peak potential (Ep,a) and cathodic peak potential (Ep,c) for reversible or quasi-reversible electrode processes or on the basis of peak potentials (in SWV) for irreversible processes. All LUMO values pertaining to this application are calculated from the following:

Formal reduction potentials vs. SCE for reversible or quasi-reversible processes;
E^{O}′_{red}=(Eₚₐ+E_{pc})/2
Formal reduction potentials vs. Fc;
E^{O}′_{red} vs. Fc=(E^{O}′_{red} vs. SCE)−E_{Fc}
where E_{Fc} is the oxidation potential Eₒₓ, of ferrocene;
Estimated lower limit for LUMO;
LUMO=HOMO_{Fc}−(E^{O}′_{red} vs. Fc)
where HOMO_{Fc} (Highest Occupied Molecular Orbital for ferrocene)=−4.8 eV.

The LUMO values for some first and second compounds are listed in Table 2. To make a selection of compounds useful in the invention, the first compound should have a lower LUMO value than its paired second compound(s).

TABLE 2

| Material | LUMO (eV) |
|---|---|
| ALQ (J-1) | −2.50 |
| Compound C-8 | −2.72 |
| Bphen (J-4) | −2.4 |
| Compound (C-1) | −2.83 |

### Example 6

### Device Fabrication for Low Voltage Electron Transport Determination

EL devices to determine if a material qualifies as a low voltage electron transport material were constructed in the following manner:

A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.

a) Over the ITO was deposited a 1 nm fluorocarbon (CFₓ) hole-injecting layer (HIL) by plasma-assisted deposition of CHF₃.

b) A hole-transporting layer (HTL) of N,N′-di-1-naphthalenyl-N,N′-diphenyl-4,4′-diaminobiphenyl (NPB) having a thickness of 75 nm was then evaporated onto a).

c) A 35 nm light-emitting layer (LEL) of tris(8-quinolinolato)aluminum (III) (Alq) was then deposited onto the hole-transporting layer.

d) A 35 nm layer of the material to be tested for low voltage electron transport properties as exemplified in Table 3 were then deposited onto the light-emitting layer.

e) On top of the ETL was deposited a 0.5 nm layer of LiF.

f) On top of the LiF layer was deposited a 130 nm layer of Al to form the cathode.

The above sequence completed the deposition of the EL device. The device was then hermetically packaged in a dry glove box for protection

The further layer as described in the invention contains a first compound and a second compound. The second compound is a low voltage electron-transporting compound. The combination of both the first and second compounds in the further layer of the invention in the aforementioned ratios, give devices that have reduced drive voltages that are even lower when compared to the devices in which either the first or second compound are incorporated alone in said layer.

Low voltage electron transport materials are materials that when incorporated alone into the electron transporting layer, as described in paragraph d) of the current device result in drive voltages of 13 volts or less. Low voltage electron transport materials with drive voltages of 10 volts or less are also useful as second compounds of the invention while materials of 8 volts or less are preferred as second compounds. Materials tested for low drive voltages and the results are shown in Table 3.

TABLE 3
Low Voltage Electron Transport Materials

| | | | Drive |
|---|---|---|---|
| Sample | Material | Type | Voltage [symbol] |
| 1 | J-1 | Low | 8.0 |
| 2 | J-5 | Low | 9.9 |
| 3 | J-6 | Low | 8.3 |
| 4 | C-4 | High | 13.7 |
| 5 | C-7 | High | 15.4 |
| 6 | C-10 | High | 16.5 |
| 7 | CBP | High | 14.3 |

Table 3 shows that compounds J-1, J-5 and J-6 qualify as low voltage electron transport materials while C-4, C-7, C-10 and CBP do not.

As can be seen in Example 2 of Table 1, the addition of a low-voltage electron-transporting material (BPhen in this example) to a prior-art electron-transporting layer reduces the drive voltage and shows good luminous efficiency, but shows an unacceptable change in color relative to the standard Example 1. However, when the low-voltage electron-transporting material is used in conjunction with a polycyclic aromatic hydrocarbon compound (Compound C-8) with the lowest LUMO value of the compounds in the layer and with the metal lithium (Examples 4 and 5), the results show a reduced drive voltage and an improvement in the luminous efficiency while showing a much smaller color shift. A similar example with a polycyclic aromatic hydrocarbon compound with the lowest LUMO value of the compounds in the layer and a low-voltage electron-transporting material, but without a metal doped in the layer (Example 3) does not show a reduced drive voltage and the relative luminous efficiency is greatly reduced. This shows that the combination of a polycyclic aromatic hydrocarbon compound that has the lowest LUMO value of the compounds in the layer, a second compound exhibiting a higher LUMO value that is also a low voltage electron-transporting material, and a metallic material based on a metal having a work function less than 4.2 eV as described herein in this invention provides the advantages of operating the OLED device at a lower voltage without a color shift that is sometimes seen with other materials that provide a lower operating voltage.

The invention has been described in detail with particular reference to certain preferred embodiments thereof, but it will be understood that variations and modifications can be effected within the spirit and scope of the invention.

### PARTS LIST

100 white-light-emitting OLED device
110 substrate
120 anode
130 hole-injecting layer (HIL)
132 hole-transporting layer (HTL)
134 light-emitting layer (LEL)
135 light-emitting layer (LEL)
136 electron-transporting layer (ETL)
138 electron-injecting layer (EIL)
140 cathode
150 voltage/current source
160 electrical connectors

1. An OLED device comprising:
a) a cathode, an anode, one or more light-emitting layers disposed between the anode and cathode to produce white light; and
b) a layer disposed between the light-emitting layer(s) and the cathode including:
i) a polycyclic aromatic hydrocarbon compound that has the lowest LUMO value of the compounds in the layer, in an amount greater than or equal to 10% by volume and less than 100% by volume of the layer;
ii) at least one second compound exhibiting a higher LUMO value than the polycyclic aromatic hydrocarbon compound, where at least one of the second compounds is a low voltage electron-transporting material, and the total amount of such second compounds(s) is less than or equal to 90% by volume of the layer; and
iii) a metallic material based on a metal having a work function less than 4.2 eV.

2. The OLED device of claim 1 wherein the second compound is phenanthroline or a derivative thereof.

3. The OLED device of claim 1 wherein the second compound is a metal oxinoid.

4. The OLED device of claim 1 wherein the polycyclic aromatic hydrocarbon compound is represented by Formula A: 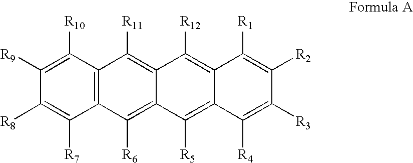
wherein:
R₁, R₂, R₃, R₄, R₅, R₆, R₇, R₈, R₉, R₁₀, R₁₁, and R₁₂ are independently selected as hydrogen or substituents;
provided that any of the indicated substituents can join to form further fused rings.

5. The OLED device of claim 4 wherein the metallic material includes Li or Cs.

6. The OLED device of claim 4 wherein at least one of R₁, R₂, R₃, R₄, R₅, R₆, R₇, R₈, R₉, R₁₀, R₁₁, and R₁₂ are independently selected from alkyl and aryl groups.

7. The OLED device of claim 4 wherein the polycyclic aromatic hydrocarbon compound is rubrene or a derivative thereof.

8. The OLED device of claim 7 wherein the second compound is a phenanthroline, a triazine, a silole or silacyclopentadiene or a derivative thereof.

9. The OLED device of claim 8 wherein the metallic material includes Li or Cs.

10. The OLED device of claim 7 wherein the second compound is a metal oxinoid.

11. The OLED device of claim 10 wherein the metallic material includes Li or Cs.

12. An OLED device comprising:
a) an anode;
b) a hole-transporting layer disposed over the anode;
c) a yellow, orange, or red light-emitting layer disposed over the hole-transporting layer;
d) a blue light-emitting layer disposed directly on the yellow, orange, or red light-emitting layer;
e) an electron-transporting layer disposed over the blue-light-emitting layer, wherein the electron-transporting layer includes:
i) a polycyclic aromatic hydrocarbon compound that has the lowest LUMO value of the compounds in the layer, in an amount greater than or equal to 10% by volume and less than 100% by volume of the layer;
ii) at least one second compound exhibiting a higher LUMO value than the polycyclic aromatic hydrocarbon compound, where at least one of the second compounds is a low voltage electron transport material, the total amount of such second compounds(s) being less than or equal to 90% by volume of the layer; and
iii) a metallic material based on a metal having a work function less than 4.2 eV; and
f) a cathode disposed over the electron-transporting layer.

13. The OLED device of claim 12 wherein the second compound is phenanthroline or a derivative thereof.

14. The OLED device of claim 12 wherein the second compound is a metal oxinoid.

15. The OLED device of claim 12 wherein the polycyclic aromatic hydrocarbon compound is represented by Formula A: 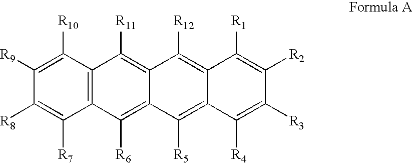
wherein:
R₁, R₂, R₃, R₄, R₅, R₆, R₇, R₈, R₉, R₁₀, R₁₁, and R₁₂ are independently selected as hydrogen or substituents;
provided that any of the indicated substituents can join to form further fused rings.

16. The OLED device of claim 15 wherein the metallic material includes Li or Cs.

17. The OLED device of claim 15 wherein at least one of R₁, R₂, R₃, R₄, R₅, R₆, R₇, R₈, R₉, R₁₀, R₁₁, and R₁₂ are independently selected from alkyl and aryl groups.

18. The OLED device of claim 15 wherein the polycyclic aromatic hydrocarbon compound is rubrene or a derivative thereof.

19. The OLED device of claim 18 wherein the second compound is phenanthroline or a derivative thereof.

20. The OLED device of claim 19 wherein the metallic material includes Li or Cs.
